(19) United States
(12) Patent Application Publication
(10) Pub. No.: US 2014/0231880 A1
(43) Pub. Date: Aug. 21, 2014

(54) IMAGING SENSOR

(71) Applicant: THE SECRETARY OF STATE FOR DEFFENCE, Sailsbury, Wiltshire (GB)

(72) Inventor: Christopher David Burgess, Sailsbury (GB)

(21) Appl. No.: 14/346,345

(22) PCT Filed: Sep. 24, 2012
(86) PCT No.: PCT/GB2012/000738

§ 371 Date: Mar. 21, 2014

(30) Foreign Application Priority Data
Sep. 29, 2011 (GB) 1116780.6

(51) Int. Cl. H01L 27/148

(52) U.S. Cl. CPC H01L 27/14887; H01L 27/14806
USPC 257/230

(57) ABSTRACT

An imaging sensor of the charge transfer type that limits the transmission of radiation from high intensity light sources. The invention addresses potential saturation levels during exposure or stare time and so saturation is never achieved, this provides for a wider dynamic range.

### TECHNICAL FIELD OF THE INVENTION

This invention relates to an imaging sensor of the charge transfer type and more particularly to an imaging sensor of the charge transfer type that limits the transmission of radiation from high intensity light sources.

Saturation and blooming effects caused by high intensity light sources such as sunlight, welding arc, car head lamps or lasers which are directed at an optical system or device, are a common problem. They cause degradation of image quality or loss of situational awareness for the user and often damage to the sensor pixel array.

Most imaging sensors operate by converting an optical image into an electrical pattern commonly known in the art as charge transfer type sensors. Often this electrical pattern takes the form of a collection of charge carriers, negatively charged electrons or positively charged holes. These carriers are created in photosensitive materials, materials in which the charge carriers may be generated by the absorption of a light photon. When the photosensitive material is exposed to light radiation for a given length of time, the generated number of electrons or holes within each part of the image is counted electronically and converted into a picture for the user to observe.

Overexposure of the photosensitive material can lead to unwanted effects within the sensor such as saturation or blooming effects. For a pixel sensor, saturation results when light energy fills a pixel cell to its maximum capacity and often leads to blooming. The blooming phenomenon occurs when a pixel is over-filled by light energy, and charge carriers literally ‘spill’ from one pixel to the next resulting in a bright source appearing larger than it actually is. Saturation and blooming of pixel arrays especially by laser is now a common problem, both in military and civilian environments, as lasers themselves have become smaller, cheaper and more readily available. This, in turn, has led to the need to provide such systems and devices with electro-optic protection measures (EOPM) to limit or filter the transmission of light to the sensor. Prior art such as U.S. Pat. No. 4,670,766 details imaging sensor architecture containing an additional photoconducting layer. The purpose of the additional photo conducting layer in U.S. Pat. No. 4,670,766 is to prevent the ‘blooming’ of charge between pixels, that is to remove any additional charge as it spills. The prior art removes excess charge due to saturation during read out. It does this by off loading the excess charge with a MOSFET at regular intervals. The problem with the prior art is that it does not prevent saturation and therefore is limited in its optical dynamic range (its ability to provide optical output at low intensity and high intensity light).

### SUMMARY OF THE INVENTION

It is an object of the invention to provide new sensor architecture for any imaging sensor of the charge transfer type relying upon charge collection methods that can dramatically increase the dynamic range of the sensor, protecting it from high intensity light radiation and preventing saturation and hence blooming.

Accordingly the present invention provides an imaging sensor comprising:

a pixel electrode;

a layer of photo sensitive material;

a layer of semi conductor material; a second electrode;

means to apply a potential difference across the semi conductor material and the photo sensitive material during operation;

wherein the layer of photosensitive material is positioned between the pixel electrode and the layer of semi conductor material, the photoresitivity of the photo sensitive material decreasing on exposure to light such as to increase the sensor's dynamic range.

For any individual pixel, by positioning the layer of photosensitive material between the pixel electrode and the layer of photo conductor material, then the photosensitive layer can influence the charge that is stored in that particular pixel. This is because when a potential difference is applied across the photosensitive material and semi conductor material via the pixel electrode and second electrode; by utilising a layer of photo sensitive material whereby its photosensitivity is lower than the layer of semi conductor material, the amount of charge collected within the layer of semi conductor material may be altered according to the instantaneous resistivity of the photo sensitive material. Since the resistivity of the photo sensitive material will drop on exposure to high intensity radiation, at any time that the layer of semi conductor material is exposed to high intensity light the charge collected by the sensor will drop, and the sensor will not saturate. Effectively a short circuit is created between the applied potential difference through the photo sensitive material, thus excess charge is not read off, the excess charge being drawn to the pixel electrode of the potential difference means. The advantage over the prior art is that the invention addresses potential saturation levels during exposure or stare time and so saturation is never achieved, this provides for a wider dynamic range.

A variety of materials can be used for the photosensitive layer including doped Poly Vinyl Carbazole (PVK) where the dopant can be dyes tailored to the waveband of interest; a thin layer of doped Gallium Arsenide (GaAs), the dopant can be variable amounts of Aluminium, Indium or other elements; doped Silicon Carbide, the dopant can be any transition metal; doped Gallium Phosphide (GaP) or either doped or undoped Bismuth Silicon Oxide (BSO).

A person skilled in the art will appreciate that this type of modification can in principle be made to any imaging system that relies upon the conversion of a light image into a charge pattern. These sensors include cameras, thermal cameras, liquid crystal devices, night vision equipment. A person skilled in the art will also appreciate that each distinct camera technology will require a very specifically matched added photoconductor which possesses the appropriate material properties that will allow it to function in the way suggested.

### BRIEF DESCRIPTION OF THE DRAWINGS

In order that the invention might be more fully understood, embodiments thereof will now be described, with reference to the accompanying drawings, in which:

FIG. 1 is a cross sectional view of a standard Charge Coupled Device (CCD) camera pixel based upon a silicon photo diode;

FIG. 2 is a cross sectional view of a CCD in accordance with the invention;

FIG. 3 illustrates a standard pixel response graph as light intensity increases;

FIG. 4 illustrates a response graph of a pixel using the invention.

FIG. 5 is a cross sectional view of a three pixel CCD embodiment in accordance with the invention.

FIG. 6 shows a drive pulse wave form applied to the embodiment of FIG. 5.

FIG. 7 shows the embodiment of FIG. 5 and the position of charge carriers when a voltage V1 is applied.

FIG. 8 shows the embodiment of FIG. 5 and the position of charge carriers when a voltage V2 is applied.

FIG. 9 shows the embodiment of FIG. 5 and the position of charge carriers when a voltage V3 is applied.

### DETAILED DESCRIPTION

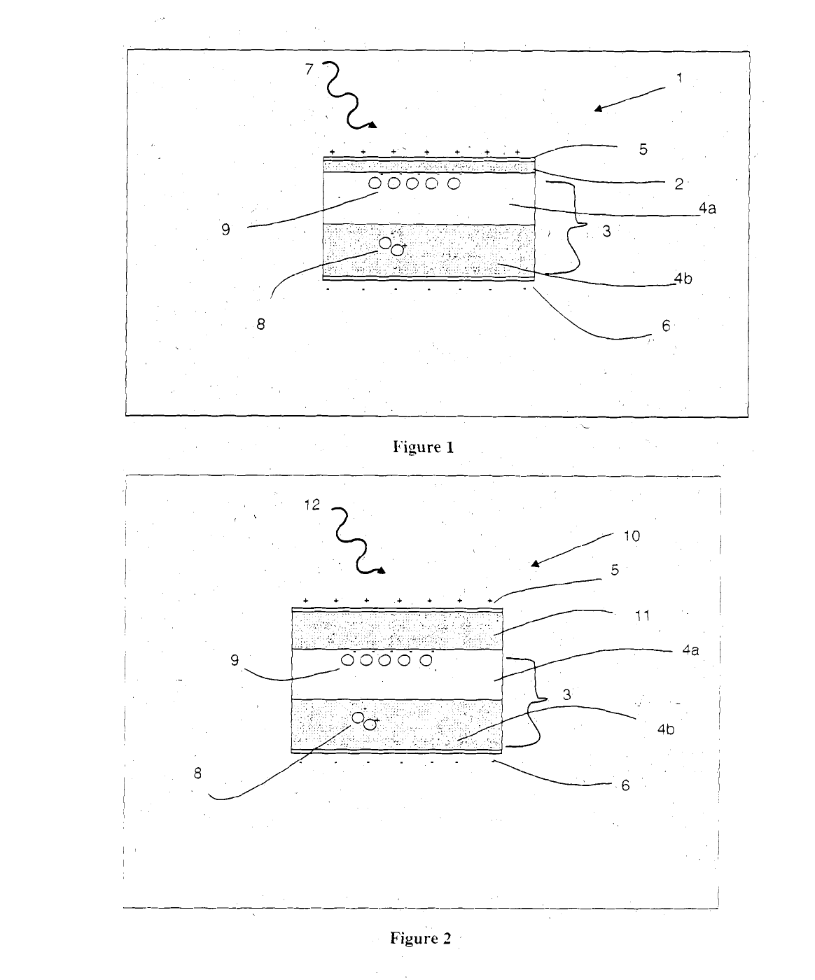

FIG. 1 shows a representative cross section of a single CCD pixel 1. The CCD pixel 1 is constructed from an insulating layer 2, a semi conductor material 3 comprising an n-type doped silicon layer 4a and a p-type doped silicon layer 4b. The insulating layer 2 and semi conductor material 3 are sandwiched between two electrodes 5 & 6. A pixel electrode 5 is positively charged and a second electrode 6 is negatively charged by a voltage supply (not shown). Incoming light 7 is converted into charge carriers 8 which results in a charge pattern 9, made up of negatively charged electrons which are attracted to the positively charged pixel electrode 5. The charge pattern 9 can then be “read out” from the silicon by the application of a modulated voltage across the silicon surface. This effectively sweeps the electrons into readout electronics via an amplification circuit (not shown). The positively charged pixel electrode 5 is positioned on side facing the high intensity light source.

FIG. 2 shows a representative cross section of the proposed invention used in a single CCD pixel 10. All the common features of FIG. 1 are indicated. The insulating layer 2 has been replaced by a layer of photo sensitive material 11. In the absence of high intensity light the resistivity of the photo sensitive material 11 is high and the pixel behaves as normal. If the pixel is exposed to high intensity light 12 the resistivity of the photo sensitive material 11 will drop, causing an effective electrical contact between the silicon layer 4a and the pixel electrode 5. The polarity of the pixel electrode 5 will lead to the loss of the negatively charged electrons from the material. In this way the maximum number of electrons that can be generated by light within the pixel is artificially limited and the dynamic range of the CCD greatly increased.

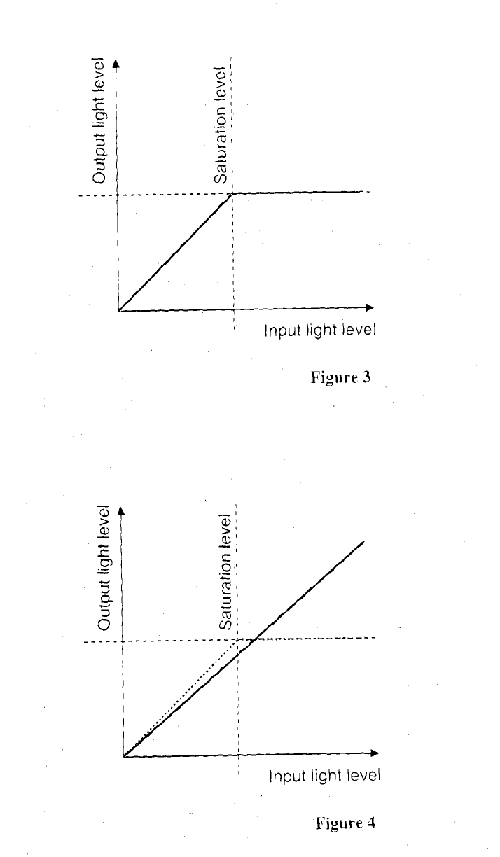

FIG. 3 shows a standard pixel response graph. Above a certain level (the saturation level) the output is saturated and does not increase with increasing input.

FIG. 4 shows the response graph of a modified (unsaturable) pixel due to the invention. Even above the normal saturation level the sensor's response remains linear. The inclusion of the photo sensitive layer is likely to reduce the sensitivity of the pixels, such that the slope of the modified line is lower.

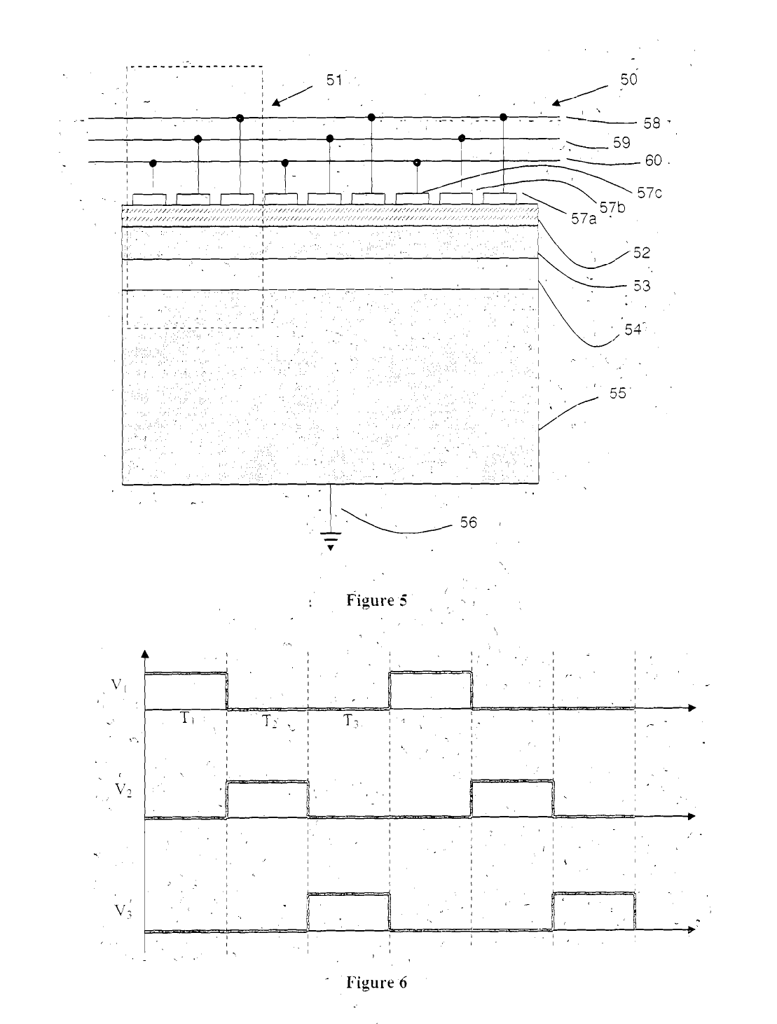

FIG. 5 is a cross sectional view of a three pixel CCD embodiment 50. A single pixel 51 is indicated by the area within the dashed line. The three pixel embodiment 50 comprises a photosensitive layer 52 formed onto a semi conductor material having a n-type silicon 53, and p-type silicon 54. The layers 52, 53 and 54 are constructed onto a semiconductor substrate 55, the substrate 55 having an electrode 56 applied to the bottom surface, in this case the electrode 56 is connected to earth. Three pixel electrodes 57a, 57b, 57c, are connected to a voltage 58 (V1), 59 (V2) and 60 (V3) respectively and each pixel electrode attached to the photosensitive layer 52. FIG. 6 shows a drive pulse wave form applied to the embodiment of FIG. 5. The pulse wave is a positive voltage supplied to the pixel electrodes 57a, 57b, 57c.

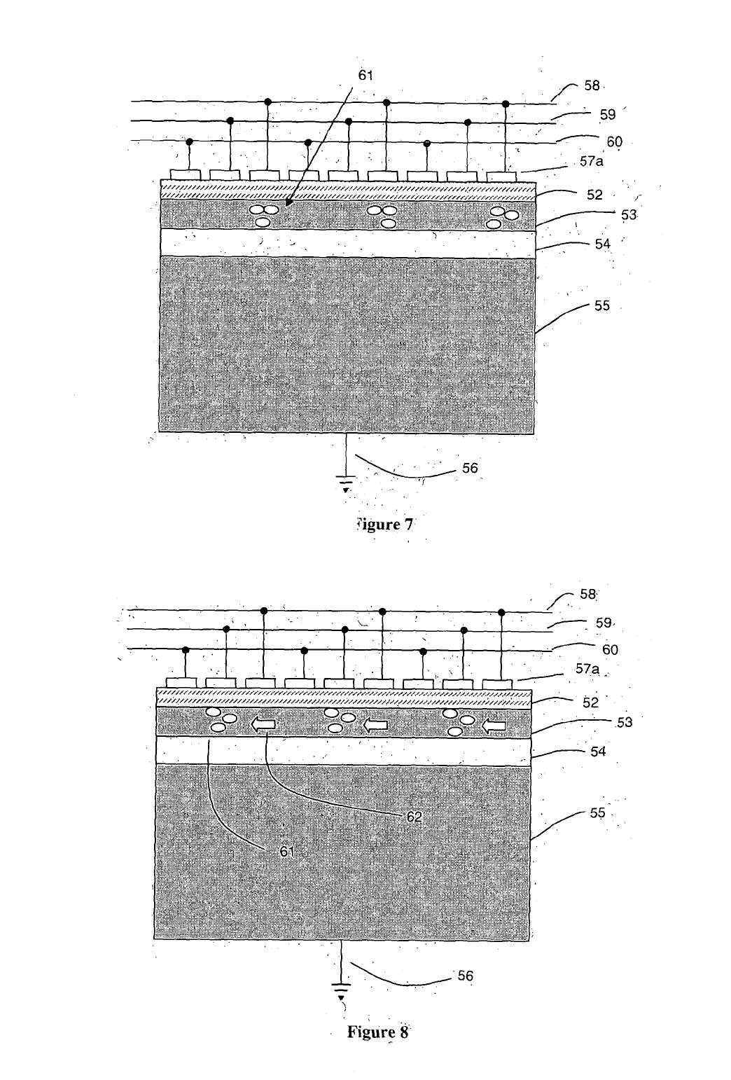

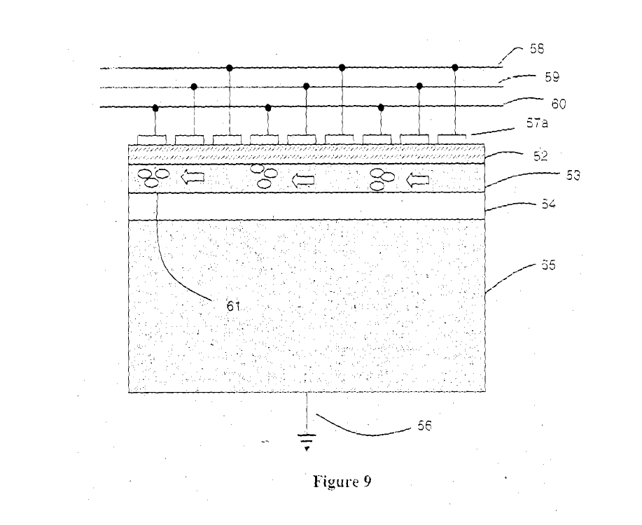

FIG. 7 shows the embodiment of FIG. 5 and the position of charge carriers when a voltage V1 is applied. FIG. 8 shows the embodiment of FIG. 5 and the position of charge carriers when a voltage V2 is applied, the arrow 62 indicating the direction of movement of the charge carriers. FIG. 9 shows the embodiment of FIG. 5 and the position of charge carriers when a voltage V3 is applied. During the image build up, one of the pixel electrodes is held at high potential relative to the earth. Charge builds up underneath this high potential region. To read out the device, the voltages on each of the three pixel electrodes are varied to ‘swipe’ the charge off the device into a readout channel (not shown). However, when an area of any pixel is overexposed to light energy, the pixel electrode that is closest to the overexposed area collects the excess charge because there is effectively a short circuit between the semi conductor material 54 and the pixel electrode. So the invention prevents excess charge build up and therefore saturation of any pixel is avoided.

1. An imaging sensor comprising:
a pixel electrode;
a layer of photo sensitive material;
a layer of semi conductor material; a second electrode;
means to apply a potential difference across the semi conductor material and the photo sensitive material during operation;
wherein the layer of photosensitive material is positioned between the pixel electrode and the layer of semi conductor material, the photoresitivity of the photo sensitive material decreasing on exposure to light such as to increase the sensor's dynamic range.

2. An imaging sensor according to claim 1 wherein the layer of photo-sensitive material is comprised of doped Poly Vinyl Carbazole (PVK).

3. An imaging sensor according to claim 1 wherein the layer of photo-sensitive material is comprised of doped Gallium Arsenide (GaAs).

4. An imaging sensor according to claim 1 wherein the layer of photo-sensitive material is comprised of doped Silicon Carbide.

5. An imaging sensor according to claim 1 wherein the layer of photo-sensitive material is comprised of doped Gallium Phosphide (GaP).

6. An imaging sensor according to claim 1 wherein the layer of photo-sensitive material is comprised of doped Bismuth Silicon Oxide (BSO).

7. An imaging sensor according to claim 1 wherein the layer of photo-sensitive material is comprised of undoped Bismuth Silicon Oxide (BSO).

8. An imaging sensor substantially as herein described with reference to FIGS. 2 and 4 to 9 of the accompanying drawings.
